(19) United States
(12) Patent Application Publication
(10) Pub. No.: US 2025/0105055 A1
(43) Pub. Date: Mar. 27, 2025

(54) ETCH STOP LAYERS

(71) Applicant: Taiwan Semiconductor Manufacturing Company, Ltd., Hsinchu (TW)

(72) Inventors: Chung-Ren Sun, Kaohsiung City (TW); Kai-Shiung Hsu, Hsinchu City (TW); Shih-Chi Lin, Hsinchu City (TW); Huai-Tei Yang, Hsinchu City (TW); Su-Yu Yeh, Tainan City (TW)

(21) Appl. No.: 18/531,007

(22) Filed: Dec. 6, 2023

Related U.S. Application Data
(60) Provisional application No. 63/585,440, filed on Sep. 26, 2023.

(51) Int. Cl. H01L 21/768; H01L 23/522; H01L 23/532

(52) U.S. Cl. CPC H01L 21/76832; H01L 21/76807; H01L 21/76826; H01L 23/5226; H01L 23/53238

(57) ABSTRACT

Contact structures and methods of forming the same are provided. A method according to the present disclosure includes receiving a workpiece including a conductive feature embedded in a first dielectric layer, treating the workpiece with a nitrogen-containing plasma, after the treating, depositing a first etch stop layer (ESL) over the workpiece, depositing a second ESL over the first ESL, depositing a second dielectric layer over the second ESL, forming an opening through the second dielectric layer, the second ESL and the first ESL to expose the conductive feature, and forming a contact via in the opening. The first ESL includes aluminum nitride or silicon carbonitride and the second ESL includes aluminum oxide or silicon oxycarbide.

### PRIORITY DATA

The present application claims the benefit of U.S. Provisional Application No. 63/585,440, filed Sep. 26, 2023, the entirety of which is herein incorporated by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As device dimensions continue to shrink, back-end-of-line (BEOL) interconnect structures are subject to tighter power, performance and area (PPA) process windows and requirements. Etch stop layers in the BEOL play important roles in reducing leakage, improving adhesion, improving resistance-capacitance matching, or lowering resistive-capacitive delay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method 100 for forming a contact structure, according to one or more aspects of the present disclosure.

FIGS. 2-16 are fragmentary cross-sectional views of a workpiece at various stages of fabrication according to the method in FIG. 1, according to one or more aspects of the present disclosure.

FIG. 17 is a flowchart of a method 400 for forming a contact structure, according to one or more aspects of the present disclosure.

FIGS. 18-25 are fragmentary cross-sectional views of a workpiece at various stages of fabrication according to the method in FIG. 17, according to one or more aspects of the present disclosure.

FIG. 26 illustrates a fragmentary cross-sectional view of a fin-type field effect transistor (FinFET) 500 and contact structures connected thereto, according to one or more aspects of the present disclosure.

FIG. 27 illustrates a fragmentary cross-sectional view of a gate-all-around (GAA) transistor 600 and contact structures connected thereto, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Source/drain region(s) may refer to a source or a drain, individually or collectively, dependent upon the context.

As device dimensions continue to shrink, the industry works hard to keep up with Moore's Law. When the front-end-of-line (FEOL) devices becomes smaller, the back-end-of-line (BEOL) interconnect structures play a greater role in keeping up with the power, performance and area requirements. For example, the BEOL interconnect structures may include dielectric layers of low dielectric constants (low-k) to keep the parasitic capacitance down. In order to achieve etch end point detection, etch stop layers (ESLs) that are more etch resistant than the low-k dielectric layers may be deposited to provide different etch rates. Existing etch stop layers may not have sufficiently large process windows when applied to device structures that have fine-pitch metal, thick metal structures, radio frequency (RF) device, and high performance computing (HPC) device.

The present disclosure provides several etch stop layer (ESL) structures to meet different device performance requirements. When used over a copper conductive feature in a dielectric layer, the copper conductive feature and the dielectric layer are first subject to a plasma treatment. A metal nitride layer or a nitrogen-doped silicon carbide layer may be deposited over the copper conductive feature as a lower ESL. A metal oxide layer or an oxygen-doped silicon carbide layer may be deposited over the lower ESL as an upper ESL. In some embodiments where the lower ESL includes metal nitride and the upper ESL includes metal oxide, a middle ESL may be deposited to improve adhesion between the lower and upper ESLs. When used over a tungsten conductive feature in a dielectric layer, a metal oxide layer may be deposited over the tungsten conductive feature and the dielectric layer as a lower ESL to improve adhesion. A metal nitride layer or another metal oxide layer may be deposited over the lower ESL as an upper ESL.

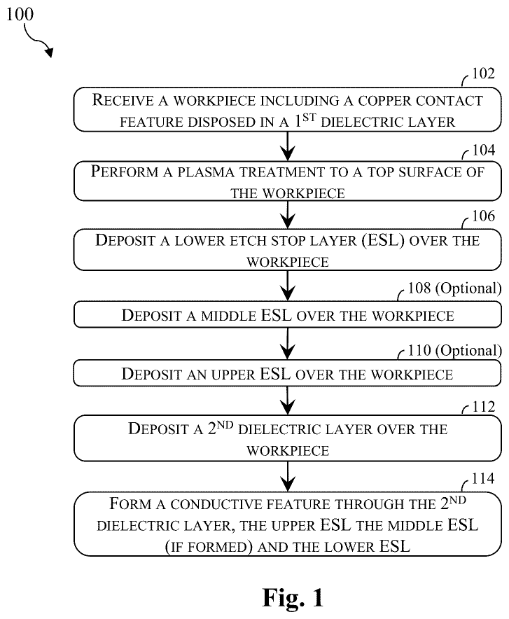

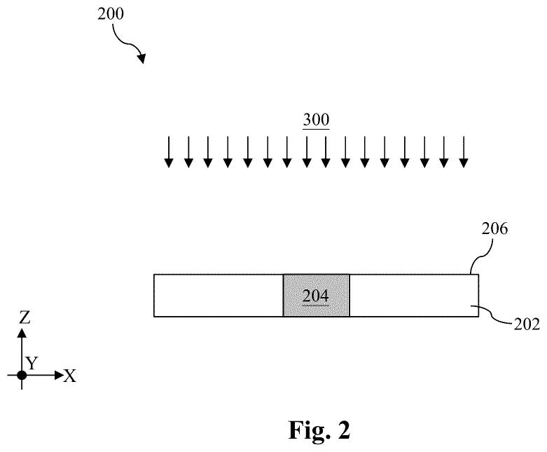

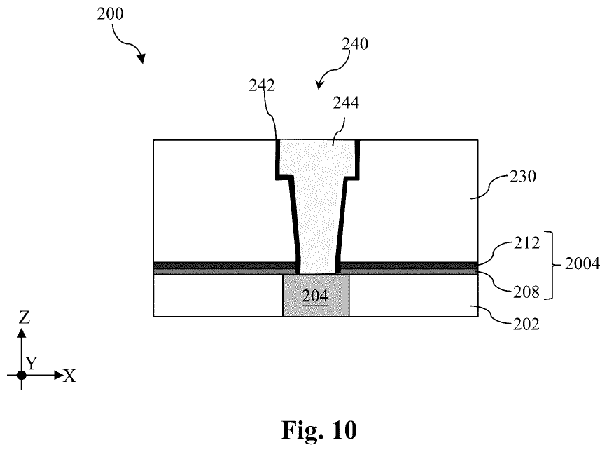

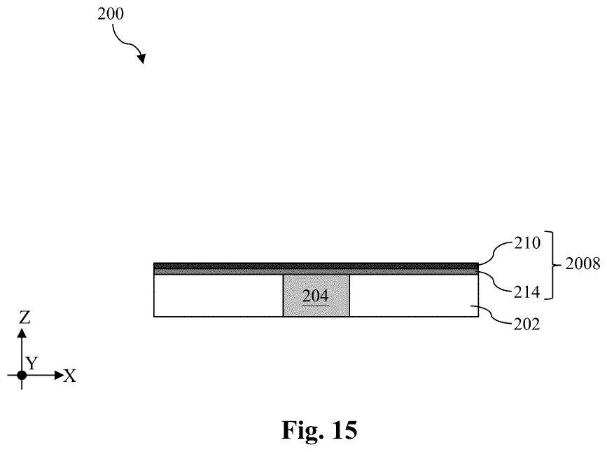

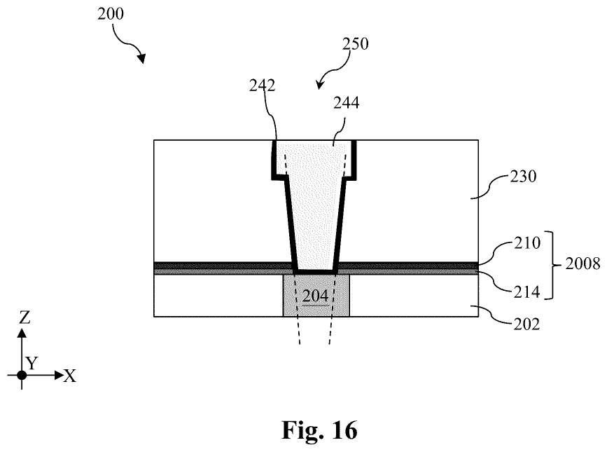

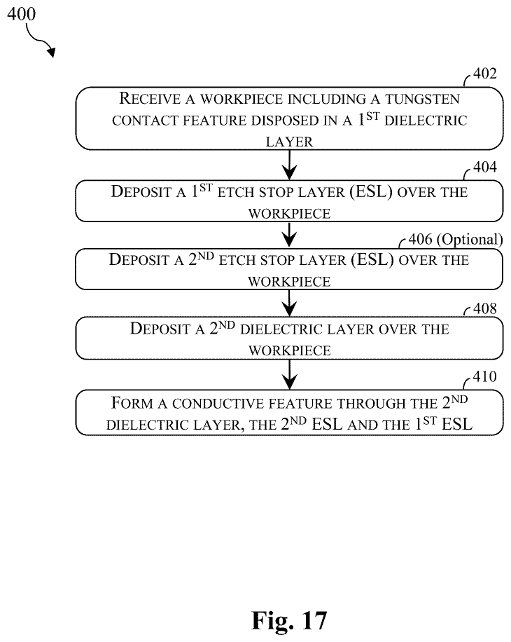

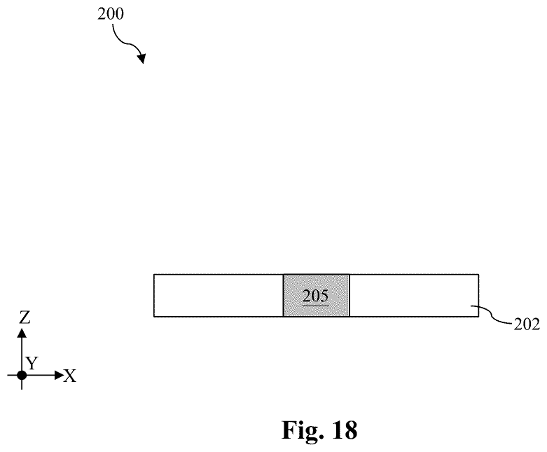

The various aspects of the present disclosure will now be described in more detail with reference to the figures. In that regard, FIGS. 1 and 17 are flowcharts illustrating method 100 and method 400 for forming a contact structure on a workpiece 200. Methods 100 and 400 are merely examples and are not intended to limit the present disclosure to what is explicitly illustrated in method 100 or method 400. Additional steps may be provided before, during and after method 100 or method 400, and some steps described can be replaced, eliminated, or moved around for additional embodiments of the method 100 or method 400. Not all steps are described herein in detail for reasons of simplicity. Method 100 is described below in conjunction with FIGS. 2-16, which are fragmentary cross-sectional views of a workpiece 200 at different stages of fabrication according to embodiments of method 100. Method 400 is described below in conjunction with FIGS. 18-25, which are fragmentary cross-sectional views of a workpiece 200 at different stages of fabrication according to embodiments of method 400. Because the workpiece 200 will be fabricated into a semiconductor structure 200 upon conclusion of the fabrication processes, the workpiece 200 may be referred to as a semiconductor structure 200 as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

Referring to FIGS. 1 and 2, method 100 includes a block 102 where a workpiece 200 that includes a first contact feature 204 disposed in a first dielectric layer 202 is received. The first contact feature 204 includes copper (Cu) and may also include cobalt (Co) or nickel (Ni). The first contact feature 204 ay be a metal line, a contact via, or a source/drain contact. The first dielectric layer 202 may be an interlayer dielectric (ILD) layer or an intermetal dielectric (IMD) layer. In some embodiments, the first dielectric layer 202 may include silicon oxide or a low-k dielectric material with a k-value (dielectric constant) smaller than that of silicon oxide, which is about 3.9. In some embodiments, the low-k dielectric material includes a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), spin-on silicon based polymeric dielectrics, or combinations thereof. While not explicitly illustrated in the figures, the first contact feature 204 may be spaced apart from the first dielectric layer 202 by a barrier layer. The barrier layer may include titanium nitride (TiN), cobalt nitride (CON), manganese nitride (MnN), nickel nitride (NiN), tungsten nitride (WN), or tantalum nitride (TaN). As shown in FIG. 2, top surfaces of the first contact feature 204 and the first dielectric layer 202 may be coplanar as a result of a planarization process.

Referring to FIGS. 1 and 2, method 100 includes a block 104 where a plasma treatment 300 is performed to a top surface of the workpiece 200. To passivate the top surface of the first contact feature 204 and to improve adhesion between the first contact feature 204 and the lower ESL 208, the top surface of the workpiece 200 is treated with a plasma treatment 300. The plasma treatment 300 includes use of plasma of ammonia (NH₃) and nitrogen (N₂) and may create a nitrogen-rich top surface 206 on the workpiece 200. Before the plasma treatment 300, a top surface of the first contact feature 204 may be oxidized to include copper oxide due to the planarization process or exposure to oxygen and a top surface of the first dielectric layer 202 may include dangling bonds, oxygen bond and alkyl groups. Experimental results show that the plasma treatment 300 may reduce the surface copper oxide to copper, remove dangling bonds, or replace alkyl group with nitrogen atoms. Additionally, the plasma treatment 300 at block 104 may create low orbital metal to nitrogen bonds such as nitrogen to copper bonds. The surface reduction and nitridation brought about by the plasma treatment promotes adhesion and reduce electromigration of copper. In some implementations, a ratio of a flow rate of nitrogen (N₂) and a flow rate of ammonia (NH₃) in the plasma treatment 300 may be between about 45 and about 15.

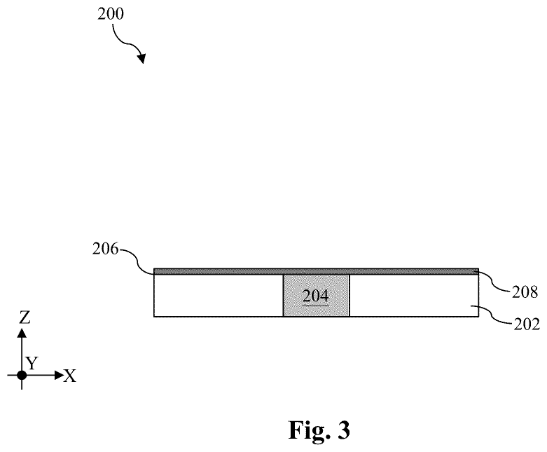

Referring to FIGS. 1 and 3, method 100 includes a block 106 where a lower etch stop layer (ESL) 208 is deposited over the workpiece 200. In some embodiments, the lower ESL 208 may include a metal nitride, such as aluminum nitride (AlN). When the lower ESL 208 includes aluminum nitride (AlN), the lower ESL 208 may be deposited using atomic layer deposition (ALD) that includes multiple thermal ALD cycles at a temperature between about 300° C. and about 400° C. The deposition of the lower ESL 208 may include use of an aluminum-containing precursor, such as trimethylaluminum (Al(CH₃)₃) and a nitrogen-containing precursor, such as ammonia (NH₃). In some alternative embodiments, the lower ESL 208 may be deposited using chemical vapor deposition (CVD) or plasma-enhanced CVD (PECVD). In the embodiments where the lower ESL 208 includes aluminum nitride (AlN), the lower ESL 208 may have a thickness between about 20 Å and about 40 Å. Because the lower ESL 208 is deposited on the nitrogen-rich top surface 206, a bottom surface of the lower ESL 208 has a greater nitrogen content than a top surface of the lower ESL 208.

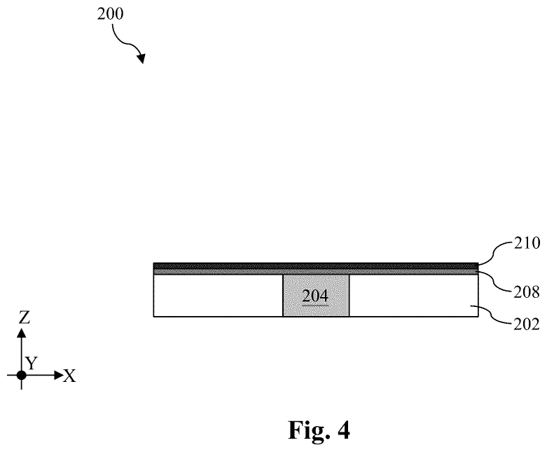

Referring to FIGS. 1 and 4, method 100 includes an optional block 108 where a middle ESL 210 is deposited over the workpiece 200. Operations at block 108 are optional. When performed, the middle ESL 210 is deposited directly on the lower ESL 208 to serve as an adhesion promotion layer between the lower ESL 208 and an upper ESL 212 (to be described below). In some embodiments, the middle ESL 210 includes oxygen-doped silicon carbide (SiC:O or O—SiC). The middle ESL 210 may be deposited using CVD or PECVD using tetramethylsilane (Si(CH₃)₄), silane (SiH₄), trimethylsilane (Si(CH₃)₃H), carbon dioxide (CO₂), xenon (Xe), oxygen (O₂), and the like. It is noted that the middle ESL 210, when formed, is purposedly and intentionally deposited with an oxygen atomic percentage between about 20% and about 30%. The middle ESL 210 not only may enhance adhesion between the lower ESL 208 and the upper ESL 212 but also suppress hillock formation in the first metal contact feature 204. When the middle ESL 210 is implemented, it may have a thickness between about 50 Å and about 100 Å. This thickness range is not trivial. When the thickness of the middle ESL 210 is smaller than 50 Å, it may not effectively suppress hillock formation. When the thickness of the middle ESL 210 is greater than 100 Å, the increased thickness may increase the parasitic capacitance too much. In some embodiments, operations at block 108 are omitted and the upper ESL 212 is deposited directly on the lower ESL 208.

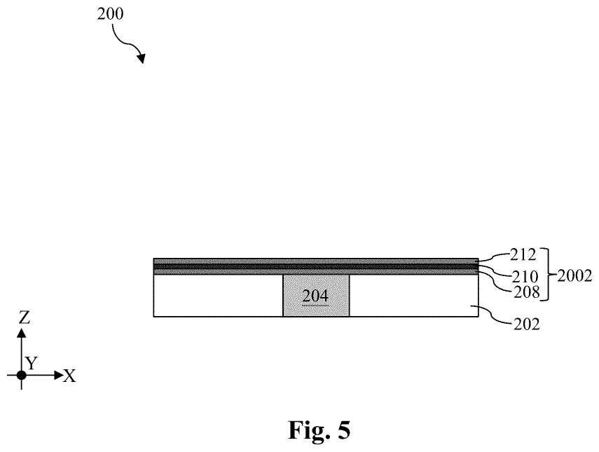

Referring to FIGS. 1 and 5, method 100 includes an optional block 110 where an upper ESL 212 is deposited over the workpiece 200. Operations at block 110 are also optional. When performed, the upper ESL 212 is deposited directly on the middle ESL 210 (when operations at block 108 are performed) or on the lower ESL 208 (when operations at block 108 are not performed. The upper ESL 212 includes a metal oxide. In some embodiments, the upper ESL 212 may include aluminum oxide (AlO), hafnium silicate (HfSiO₄) or hafnium aluminum oxide (HfAlO). In one embodiment, the upper ESL 212 includes aluminum oxide. The upper ESL 212 may be deposited using CVD, ALD, PECVD, or plasma-enhanced ALD (PEALD). The upper ESL 212 and the lower ESL 208 may have the same thickness to facilitate etch end point detection. In some instances, the upper ESL 212 may have a thickness between about 20 Å and about 40 Å. For ease of reference, the lower ESL 208, the middle ESL 210 and the upper ESL 212 may be collectively referred to as a first ESL stack 2002. While not explicitly shown in the figures, an oxygen-doped silicon carbide (SiC:O or O—SiC) may be deposited over the upper ESL 212 to improve adhesion with a subsequently-formed low-k dielectric layer, such as the second dielectric layer 230.

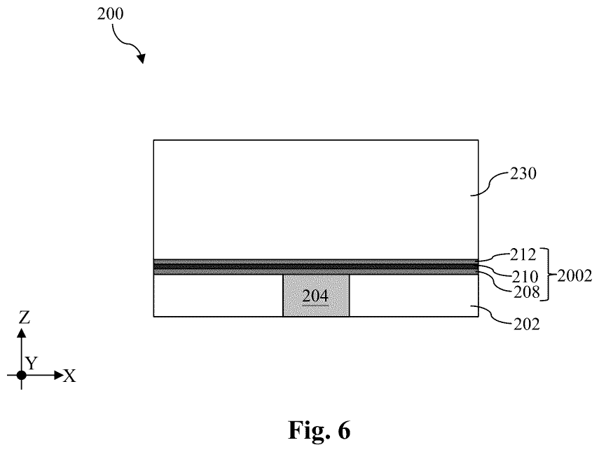

Referring to FIGS. 1 and 6, method 100 includes a block 112 where a second dielectric layer 230 is deposited over the workpiece 200. In some embodiments, a composition of the second dielectric layer 230 may be similar to that of the first dielectric layer 202. In some implementations, the second dielectric layer 230 may be deposited over the upper ESL 212 using spin-on coating, CVD, or flowable chemical vapor deposition (FCVD). In some instances, in order to improve the quality and density of the second dielectric layer 230 to withstand the subsequent patterning operations, an anneal process may be performed to improve the quality of the second dielectric layer 230. After deposition of the second dielectric layer 230, a planarization process, such as a chemical mechanical polishing (CMP) process may be performed to the second dielectric layer 230 to provide a planar top surface.

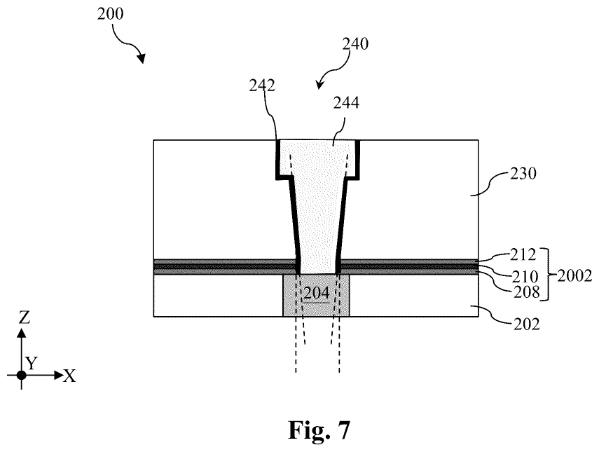

Referring to FIGS. 1 and 7, method 100 includes a block 114 where a first conductive feature 240 is formed through the second dielectric layer 230, the upper ESL 212, the middle ESL 210, and the lower ESL 208. Operations at block 114 may include formation of a dual damascene opening through the second dielectric layer 230, the upper ESL 212, the middle ESL 210 (when formed), and the lower ESL 208 to expose the first contact feature 204 and formation of the first conductive feature 240 in the dual damascene opening. In an example process, a first patterned mask is first formed by photolithography processes and a dry etch process is performed to form a via opening through the second dielectric layer 230 and the first ESL stack 2002. Then a second patterned mask is formed and another dry etch process is performed to form a trench opening that overlaps with the via opening. The dry etches at block 114 may implement an oxygen-containing gas, hydrogen, a fluorine-containing gas (e.g., CF₄, SF₆, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some implementations, the fluorine in the dry etch process may form compounds or polymers with the upper ESL 212, the lower ESL 208, and the first contact feature 204. These compounds or polymers may be redeposited in the dual damascene opening. To remove these compounds and polymers, a wet cleaning process may be performed. In some instances, the wet cleaning process may include ammonium hydroxide (NH₄OH) and a copper corrosion inhibitor. The copper inhibitor may include, for example, 5-methyl-1H-benzotriazole (MBTA) and 1H-benzotriazole (BTA).

After the dual damascene opening is formed, block 114 includes depositing a barrier layer 242 in the dual damascene opening. In some embodiments, the barrier layer 242 may include a metal nitride, such as titanium nitride, cobalt nitride, manganese nitride, nickel nitride, tungsten nitride, or tantalum nitride. In one embodiment, the barrier layer 242 includes titanium nitride. The barrier layer 242 may be deposited using chemical vapor deposition (CVD), plasma-enhanced CVD (PECVD), atomic layer deposition (ALD), or plasma-enhanced ALD (PEALD). After the barrier layer 242 is deposited, a metal fill layer 244 may be deposited over the barrier layer 242. The metal fill layer 244 may include copper (Cu), cobalt (Co), nickel (Ni), ruthenium (Ru), or tungsten (W). In one embodiment, the metal fill layer 244 includes copper (Cu). The metal fill layer 244 may be deposited using PVD, electroplating, or electroless plating. As an example, the metal fill layer 244 may be deposited using electroplating. In this example process, a seed layer may be deposited over the workpiece 200 using PVD or CVD. The seed layer may include titanium, copper, or both. Then copper is deposited over the seed layer using electroplating. After the deposition of the barrier layer 242 and the metal fill layer 244, the workpiece 200 is planarized to expose the second dielectric layer 230 to form the first conductive feature 240. The planarization may include chemical mechanical polishing (CMP). As shown in FIG. 7, the workpiece 200 is planarized until a planar top surface of the workpiece 200 includes top surfaces of the second dielectric layer 230, the barrier layer 242, and the metal fill layer 244.

As indicated by the dotted lines, a via portion of the first conductive feature 240 has a varying sidewall profile. Because the lower ESL 208 and the upper ESL 212 etch more slowly and their etching generates compound and polymers that can be redeposited over dual damascene opening, the sidewalls extending through the first ESL stack 2002 are substantially straight along the Z direction. The same cannot be said for the second dielectric layer 230. First, the second dielectric layer 230 etches much faster than the lower ESL 208 and the upper ESL 212. During the dry etching of the second dielectric layer 230, the byproducts are readily removed and are not redeposited. As such, the sidewalls extending through the second dielectric layer 230 may taper downward. As shown in FIG. 7, from the second dielectric layer 230 to the first contact feature 204, the sidewall profiles in the via portion change from downward-tapering to a lesser downward tapering along the Z direction.

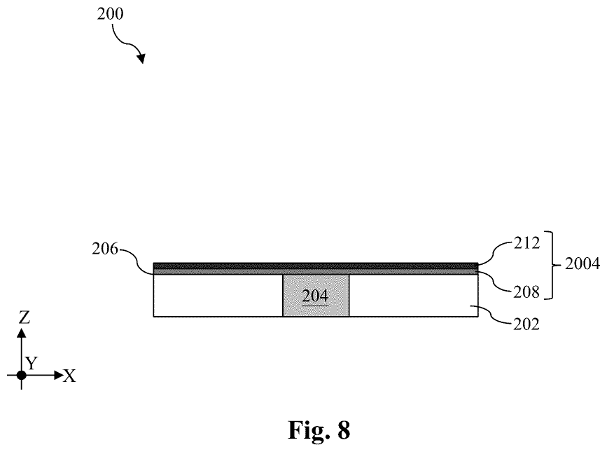

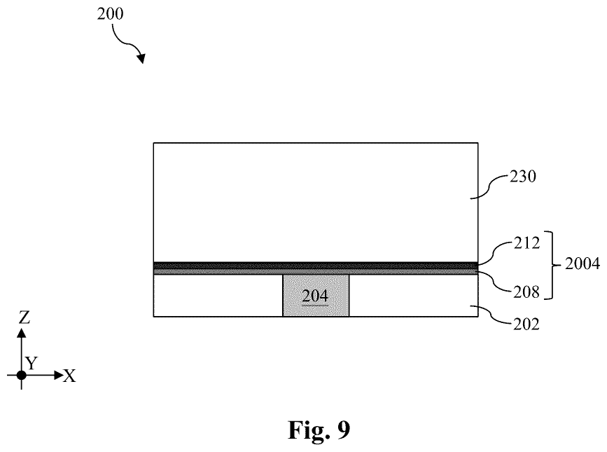

Method 100 may be applied to form alternative ESL stacks over the first contact feature 204. Reference is first made to FIGS. 8-10. In some embodiments, operations at block 108 are omitted and the middle ESL 210 is not deposited on the lower ESL 208. Referring to FIG. 8, at block 110, the upper ESL 212 is deposited directly on the lower ESL 208. The lower ESL 208 and the upper ESL 212 in FIG. 8 may be collectively referred to as a second ESL stack 2004. Method 100 then continues to block 112 that forms the second dielectric layer 230 over the second ESL stack 2004 (shown in FIG. 9). At block 114, the first conductive feature 240 is formed through the second dielectric layer 230 and the second ESL stack 2004 to contact the first contact feature 204. Because the lower ESL 208 is deposited on the nitrogen-rich top surface 206, a bottom surface of the lower ESL 208 has a greater nitrogen content than a top surface of the lower ESL 208.

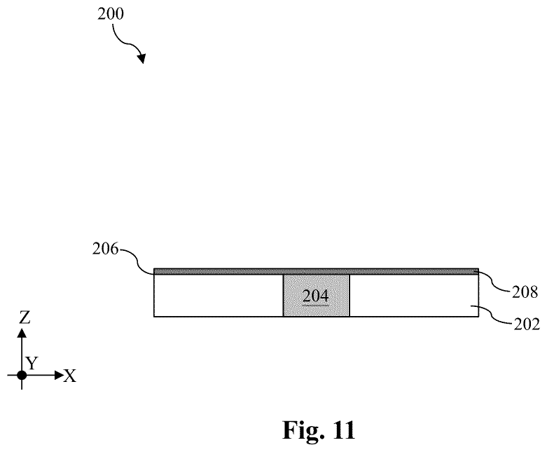

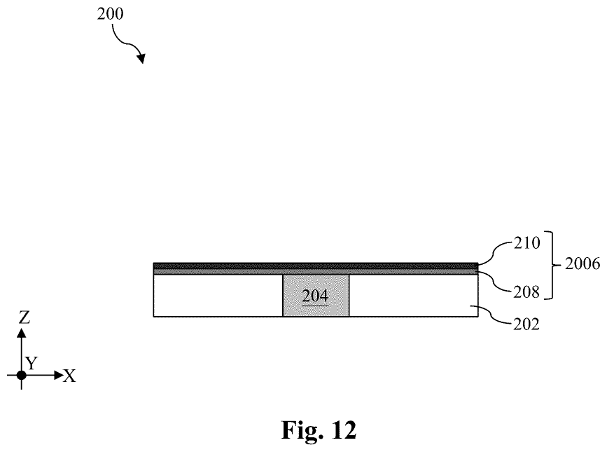

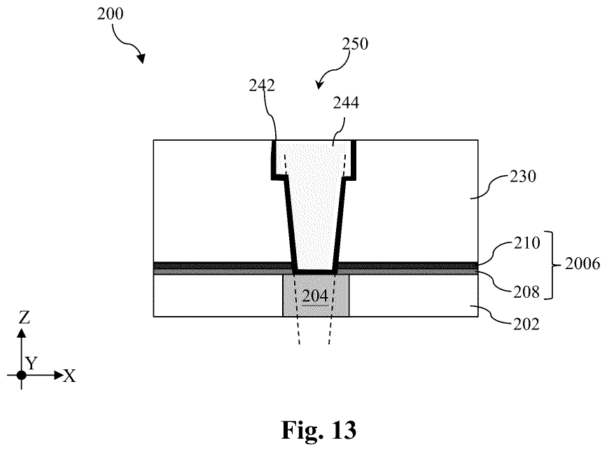

Reference is now made to FIGS. 11-13. In some embodiments, operations at block 110 are omitted and the middle ESL 210 is deposited on the lower ESL 208. Referring to FIG. 11, after the middle ESL 210 is deposited on the lower ESL 208 at block 108, method 100 skips block 110 and continues on to block 112. The lower ESL 208 and the middle ESL 210 in FIG. 12 or 13 may be collectively referred to as a third ESL stack 2006. At block 112, the second dielectric layer 230 is deposited directly on the third ESL stack 2006 (shown in FIG. 12). At block 114, the first conductive feature 240 is formed through the second dielectric layer 230 and the third ESL stack 2006 to contact the first contact feature 204. Because the lower ESL 208 is deposited on the nitrogen-rich top surface 206, a bottom surface of the lower ESL 208 has a greater nitrogen content than a top surface of the lower ESL 208.

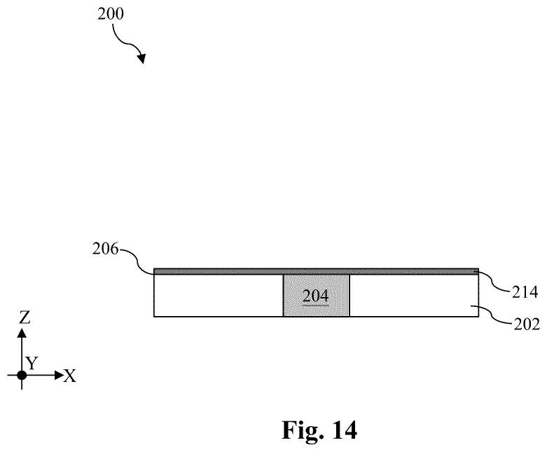

Reference is then made to FIGS. 14-16. In some embodiments, a carbide ESL 214 is deposited at block 106 in place of the lower ESL 208. In some embodiments, the carbide ESL 214 includes nitrogen-doped silicon carbide (SiC:N or N—SiC). The carbide ESL 214 may be deposited using CVD or PECVD using tetramethylsilane (Si(CH₃)₄), silane (SiH₄), trimethylsilane (Si(CH₃)₃H), ammonia (NH₃), xenon (Xe), nitrogen (N₂), and the like. It is noted that the carbide ESL 214, when formed, is purposedly and intentionally deposited with a nitrogen atomic percentage between about 20% and about 30%. In some instances, a thickness of the carbide ESL 214 may be between about 50 Å and about 100 Å. Because the carbide ESL 214 is deposited on the nitrogen-rich top surface 206, a bottom surface of the carbide ESL 214 has a greater nitrogen content than a top surface of the carbide ESL 214. At block 108, a middle ESL 210 is deposited directly on the carbide ESL 214. Operations at block 110 are omitted and the upper ESL 212 is not deposited. The carbide ESL 214 and the middle ESL 210 in FIG. 12 may be collectively referred to as a fourth ESL stack 2008. In these embodiments, the middle ESL 210 does not function to improve adhesion between the lower ESL 208 and the upper ESL 212. Instead, the middle ESL 210 functions to provide etch selectivity. For that reasons, when deposited over the carbide ESL 214, the middle ESL 210 may have a thickness similar to that of the carbide ESL 214. Method 100 then continues to block 112 that forms the second dielectric layer 230 over the fourth ESL stack 2008 (shown in FIG. 14). At block 114, a second conductive feature 250 is formed through the second dielectric layer 230 and the fourth ESL stack 2008 to contact the first contact feature 204. Like the first conductive feature 240, the second conductive feature also includes the barrier layer 242 and the metal fill layer 244. However, the second conductive feature 250 have a different sidewall profile from the first conductive feature 240. Because the carbide ESL 214 and the middle ESL 210 etch faster than the lower ESL 208 or the upper ESL 212 and their etch do not generate compounds or polymers, the sidewall profile of the via portion of the second conductive feature 250 substantially uniformly tapers downward.

Different from method 100 that is more applicable to copper-containing first contact feature 204, method 400 in FIG. 17 is more applicable to contact features that are formed of refractory metals. Method 400 will be described with reference to FIGS. 18-25, which include fragmentary cross-sectional views of the workpiece 200 at different stages of method 400.

Referring to FIGS. 17 and 18, method 100 includes a block 402 where a workpiece 200 that includes a second contact feature 205 disposed in a first dielectric layer 202 is received. The second contact feature 205 is formed of a refractory metal, such as tungsten (W) and ruthenium (Ru). In one embodiment, the second contact feature 205 includes tungsten (W). The second contact feature 205 may be a metal line, a contact via, or a source/drain contact. The first dielectric layer 202 has been described above and its detailed description will not be repeated here for brevity. While not explicitly illustrated in the figures, the second contact feature 205 may be spaced apart from the first dielectric layer 202 by a barrier layer. The barrier layer may include titanium nitride (TiN), cobalt nitride (CoN), manganese nitride (MnN), nickel nitride (NiN), tungsten nitride (WN), or tantalum nitride (TaN). Because the second contact feature 205 is less subject to electromigration, the barrier layer may be omitted. As shown in FIG. 18, top surfaces of the second contact feature 205 and the first dielectric layer 202 may be coplanar as a result of a planarization process.

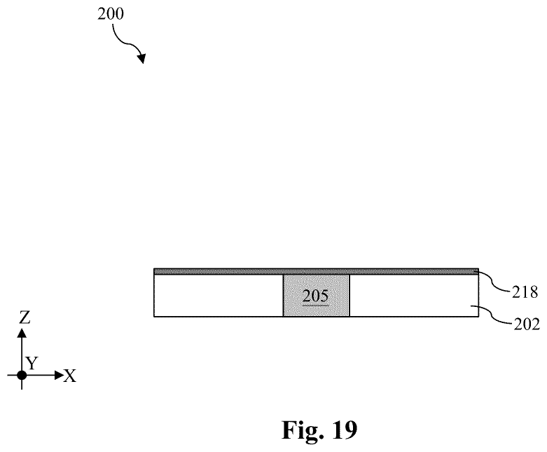

Referring to FIGS. 17 and 19, method 400 includes a block 404 where a first ESL 218 is deposited over the workpiece 200. The first ESL 218 includes a metal oxide. In one embodiments, the first ESL 218 may include aluminum oxide (AlO), hafnium silicate (HfSiO₄) or hafnium aluminum oxide (HfAlO). In one embodiment, the first ESL 218 includes aluminum oxide. The first ESL 218 may be deposited by CVD, ALD, PECVD, or plasma-enhanced ALD (PEALD) using trimethylaluminum (TMA, Al(CH₃)₃), aluminum tricholoride, nitrous oxide (N₂O), or oxygen (O₂). In some embodiments, oxygen content in the first ESL 218 may be varied over its depth by varying a flow rate of the oxygen containing precursor, such as nitrous oxide (N₂O) and oxygen (O₂). For example, in order to enhance adhesion to a silicon oxide containing dielectric layer, such as the first dielectric layer 202 or the second dielectric layer 230, the oxygen content of the contacting surface of the first ESL 218 may be increased. In some instances, the first ESL 218 may have a thickness between about 5 Å and about 20 Å.

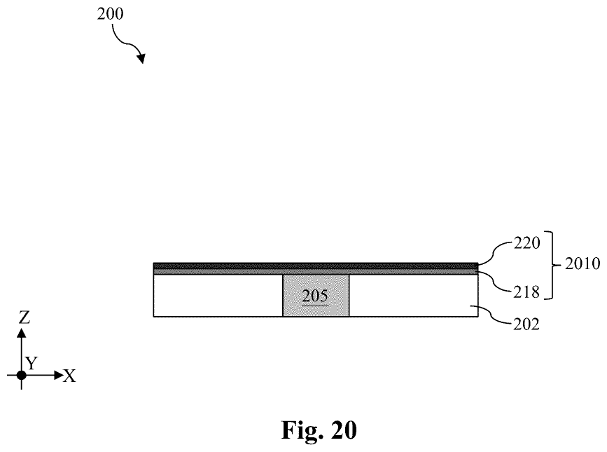

Referring to FIGS. 17 and 20, method 400 includes an optional block 406 where a second ESL 220 is deposited over the workpiece 200. Operations at block 406 are optional and may be completely omitted. The second ESL 220 may include a metal nitride. In some embodiments, the second ESL 220 includes aluminum nitride (AlN). When the second ESL 220 includes aluminum nitride (AlN), the second ESL 220 may be deposited using atomic layer deposition (ALD) that includes multiple thermal ALD cycles at a temperature between about 300° C. and about 400° C. The deposition of the second ESL 220 may include use of an aluminum-containing precursor, such as trimethylaluminum (TMA, Al(CH₃)₃) and a nitrogen-containing precursor, such as ammonia (NH₃). In some alternative embodiments, the second ESL 220 may be deposited using chemical vapor deposition (CVD) or plasma-enhanced CVD (PECVD). The second ESL 220 and the first ESL 218 may have the same thickness to facilitate etch end point detection. In some embodiments, the second ESL 220 may have a thickness between about 5 Å and about 20 Å. As shown in FIG. 20, the second ESL 220 is deposited directly on the first ESL 218. The first ESL 218 and the second ESL 220 may be collectively referred to as a fifth ESL stack 2010.

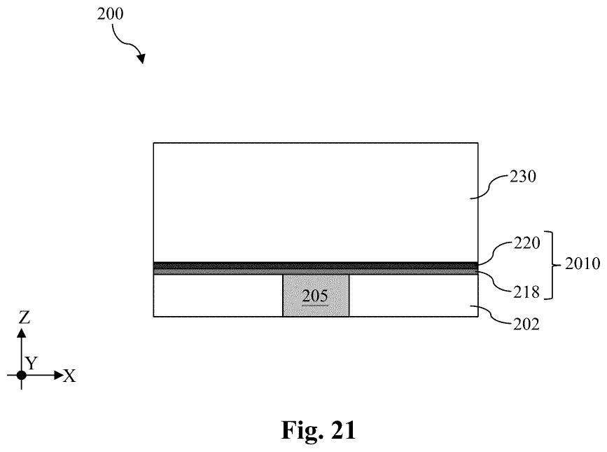

Referring to FIGS. 17 and 21, method 400 includes a block 408 where a second dielectric layer 230 is deposited over the workpiece 200. In some embodiments, a composition of the second dielectric layer 230 may be similar to that of the first dielectric layer 202. In some implementations, the second dielectric layer 230 may be deposited over the second ESL 220 using spin-on coating, CVD, or flowable chemical vapor deposition (FCVD). In some instances, in order to improve the quality and density of the second dielectric layer 230 to withstand the subsequent patterning operations, an anneal process may be performed to improve the quality of the second dielectric layer 230. After deposition of the second dielectric layer 230, a planarization process, such as a chemical mechanical polishing (CMP) process may be performed to the second dielectric layer 230 to provide a planar top surface.

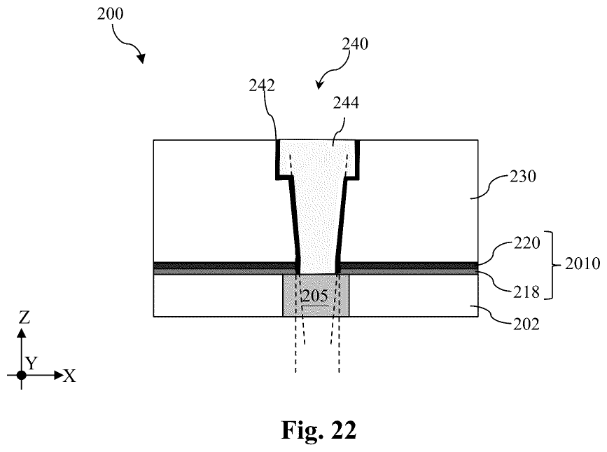

Referring to FIGS. 17 and 22, method 400 includes a block 410 where a first conductive feature 240 is formed through the second dielectric layer 230, the second ESL 220 and the first ESL 218. Operations at block 410 may include formation of a dual damascene opening through the second dielectric layer 230, the second ESL 220, and the first ESL 218 to expose the second contact feature 205 and formation of the first conductive feature 240 in the dual damascene opening. In an example process, a first patterned mask is first formed by photolithography processes and a dry etch process is performed to form a via opening through the second dielectric layer 230 and the fourth ESL stack 2008. Then a second patterned mask is formed and another dry etch process is performed to form a trench opening that overlaps with the via opening. The dry etches at block 410 may implement an oxygen-containing gas, hydrogen, a fluorine-containing gas (e.g., CF₄, SF₆, CH₂F₂, CHF₃, CH₃F, C₄H₈, C₄F₆, and/or C₂F₆), a carbon-containing gas (e.g., CO, CH₄, and/or C₃H₈), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some implementations, the fluorine in the dry etch process may form compounds or polymers with the second ESL 220, the first ESL 218, and the second contact feature 205. These compounds or polymers may be redeposited in the dual damascene opening. To remove these compounds and polymers, a wet cleaning process may be performed. In some instances, the wet cleaning process may include ammonium hydroxide (NH₄OH) and a tungsten corrosion inhibitor. The tungsten inhibitor may include, for example, benzethonium chloride. After the dual damascene opening is formed, block 410 includes depositing a barrier layer 242 in the dual damascene opening, followed by deposition of the metal fill layer 244. The composition and deposition of the barrier layer 242 and the metal fill layer 244 have been described before and will not be repeated here.

As indicated by the dotted lines in FIG. 22, a via portion of the first conductive feature 240 has a varying sidewall profile. Because the first ESL 218 and the second ESL 220 etch more slowly and their etching generates compound and polymers that can be redeposited over dual damascene opening, the sidewalls extending through the fourth ESL stack 2008 are substantially straight along the Z direction. The same cannot be said for the second dielectric layer 230. The second dielectric layer 230 etches much faster than the first ESL 218 and the second ESL 220. During the dry etching of the second dielectric layer 230, the byproducts are readily removed and are not redeposited. As such, the sidewalls extending through the second dielectric layer 230 may taper downward. As shown in FIG. 22, from the second dielectric layer 230 to the second contact feature 205, the sidewall profiles in the via portion change from downward-tapering to a lesser downward tapering along the Z direction.

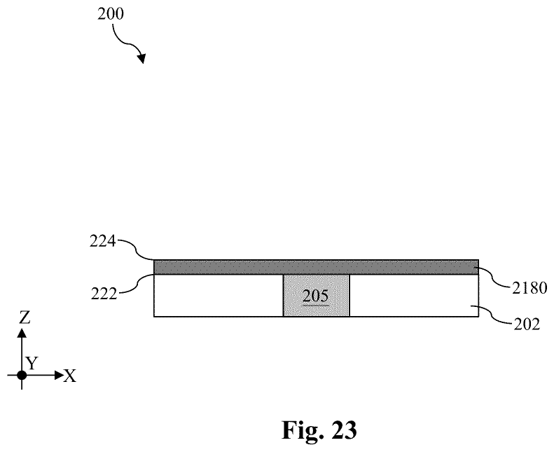

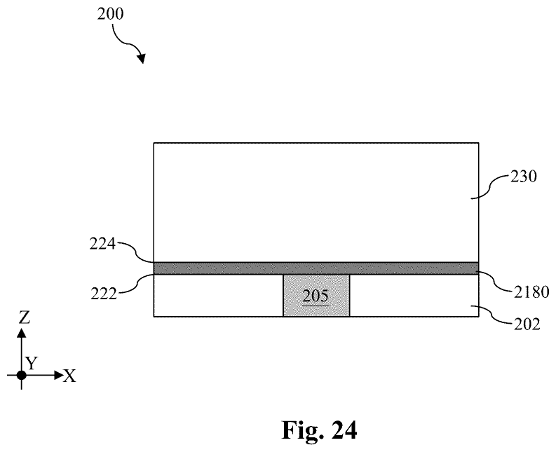

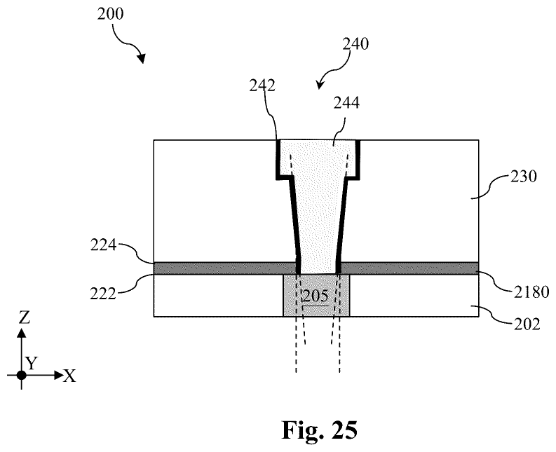

Method 400 may be applied to form alternative ESL stacks over the second contact feature 205. Reference is now made to FIGS. 23-25. In some embodiments, block 404 deposits a gradient ESL 2180, rather than the first ESL 218. While still formed of metal oxide, the gradient ESL 2180 includes an oxygen concentration gradient. As shown in FIG. 20, the gradient ESL 2180 includes a bottom surface 222 adjacent the first dielectric layer 202 and the second contact feature 205 and a top surface 224 facing away from the first dielectric layer 202 and the second contact feature 205. In the depicted embodiments, the flow rate of the oxygen containing precursor is controlled such that an oxygen content at the top surface 224 is greater than an oxygen content at the bottom surface 222. In some embodiments, the gradient ESL 2180 may have a thickness between about 10 Å and about 20 Å. An oxygen content (atomic percentage %) at the bottom surface 222 of the gradient ESL 2180 may be between about 40% to about 60% and an oxygen content at the top surface 224 of the gradient ESL 2180 may be between about 60% and about 75%. This increased oxygen content at the top surface 224 functions to improve the adhesion with the second dielectric layer 230. Operations at block 406 are omitted and the second ESL 220 is not deposited on the gradient ESL 2180. Method 400 then continues to block 408 that forms the second dielectric layer 230 over the first ESL 218 (shown in FIG. 24). At block 410, the first conductive feature 240 is formed through the second dielectric layer 230 and the gradient ESL 2180 to contact the second contact feature 205. As indicated by the dotted lines in FIG. 25, a via portion of the first conductive feature 240 has a varying sidewall profile.

The first ESL stack 2002, the second ESL stack 2004, the third ESL stack 2006, the fourth ESL stack 2008, the fifth ESL stack 2010, and the gradient ESL 2180 are suitable to be implemented at different places in a BEOL interconnect structure. For starters, as the fifth ESL stack 2010 and the gradient ESL 2180 contact the contact feature with an oxygen-containing metal oxide layer, they are more suitable to be formed over contact features that are formed of refractory metals, not copper (Cu). In contrast, because the first ESL stack 2002, the second ESL stack 2004, the third ESL stack 2006, and the fourth ESL stack 2008 contacts the underlying contact features with an oxygen-free layer, such as the lower ESL 208 or the carbide ESL 214 and their formation processes includes a plasma treatment, they are more suitable to be formed over contact features that are formed of copper (Cu). Additionally, cost effectiveness in reduction of parasitic capacitance also plays an important role in selective the ESL. A BEOL interconnect structure may include about 5 to about 20 metallization layers. Each of the metallization layers includes metal features (i.e., vias and metal lines) spaced apart from one another by IMD layers and ESLs. Depending on their distances away from the FEOL structures, metallization layers have different thicknesses. In metallization layers closer to the FEOL structures, such as the first 4 to 7 metallization layers that have line pitches greater than 90 nm, the overall thickness is smaller and the ESLs account for a greater percentage of the overall thickness. In metallization layers farther away from the FEOL structures, such as the last 6 to 15 metallization layers that have a line pitch greater than 90 nm, the overall thickness increase dramatically and the thicknesses of the ESLs may become negligible. Generally, parasitic capacitance due to an ESL is proportional to a product of a dielectric constant of the ESL and a thickness of the ESL. Metal nitride, such as aluminum nitride, has a dielectric constant between about 13 and about 15. Compared to other ESL materials that has dielectric constant smaller than 7 or so, metal nitride appears to be an unlikely choice. However, it has been observed that when serving as an ESL, metal nitride requires a much smaller thickness. In some embodiments, a thickness of a metal nitride ESL may be between about one fifth (⅕) and about one tenth ( 1/10) of a thickness of a silicon nitride ESL or a silicon carbide ESL. The smaller thickness allows the metal nitride ESL (e.g., the lower ESL 208) to give rise to a smaller capacitance. As capacitance due to ESL plays a more prominent role in lower metallization layers, implementation of the first ESL stack 2002 and the second ESL stack 2004 are more suitable for the first 4-7 metallization layer. Because capacitance due to ESL plays a negligible role in higher metallization layers and deposition of the metal nitride layer is associated with a greater cost and slow process time, implementation of the third ESL stack 2006 is more suitable for last 6 to 15 metallization layers.

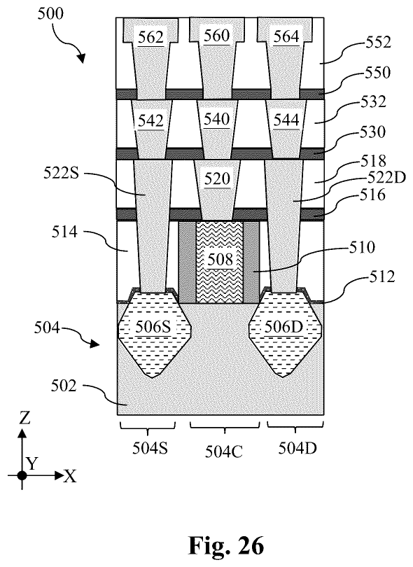

FIG. 26 illustrates implementation of ESLs to a fin-type field effect transistor (FinFET) 500. The FinFET 500 includes a fin structure 504 that rises from a substrate 502. The fin structure 504 extends lengthwise along the X direction between a source feature 506S and a drain feature 506D. The portion of the fin structure 504 between the source feature 506S and the drain feature 506D defines a channel region. A gate structure 508 wraps over the channel region of the fin structure 504. The gate structure 508 extends lengthwise along the Y direction is defined between two gate spacers 510 along the X direction. A contact etch stop layer (CESL) 512 is disposed over the source feature 506S and the drain feature 506D. An interlayer dielectric (ILD) layer 514 is disposed over the CESL 512. An ESL 516 is disposed over the gate structure 508, the gate spacers 510, and the ILD layer 514. An IMD layer 518 is disposed over the ESL 516. A source contact 522S extends through the IMD layer 518, the ESL 516, the ILD layer 514, and the CESL 512 to couple to the source feature 506S. A gate contact via 520 extends through the IMD layer 518 and the ESL 516 to coupled to the gate structure 508. A drain contact 522D extends through the IMD layer 518, the ESL 516, the ILD layer 514, and the CESL 512 to couple to the drain feature 506D. An ESL 530 is disposed over the IMD layer 518, the source contact 522S, the gate contact via 520 and the drain contact 522D. An IMD layer 532 is disposed over the ESL 530. A first contact via 540, a second contact via 542 and the third contact via 544 extend through the IMD layer 532 and the ESL 530 to couple to the gate contact via 520, the source contact 522S and the drain contact 522D, respectively. An ESL 550 is disposed over the IMD layer 532, the first contact via 540, the second contact via 542, and the third contact via 544. An IMD layer 552 is disposed over the ESL 550. A fourth contact via 560, a fifth contact via 562 and the sixth contact via 564 extend through the IMD layer 552 and the ESL 550 to couple to the first contact via 540, the second contact via 542, and the third contact via 544, respectively.

In some embodiments, the substrate 502 and the fin structure 504 may include silicon (Si). The source feature 506S and the drain feature 506D may be n-type or p-type. When they are n-type, they include silicon (Si) and an n-type dopant, such as phosphorus (P) or arsenic (As). When they are p-type, they include silicon germanium (SiGe) and a p-type dopant, such as boron (B). The gate structure 508 includes an interfacial layer to interface the fin structure 504, a gate dielectric layer over the interfacial layer, and a gate electrode over the gate dielectric layer. The interfacial layer may include silicon oxide. The gate dielectric layer may include a high-k dielectric material, such as hafnium oxide. The gate electrode may include titanium nitride, titanium aluminum, titanium aluminum nitride, titanium, tantalum, or tungsten. The gate spacers 510 may include silicon oxide, silicon nitride, silicon oxynitride, silicon oxycarbonitride, or silicon oxycarbide. The CESL 512 may include silicon nitride or silicon oxynitride. The ILD layer 514, the IMD layer 518, the IMD layer 532 and the IMD layer 552 may include a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), spin-on silicon based polymeric dielectrics, or combinations thereof. The source contact 522S and the drain contact 522D may include cobalt (Co), nickel (Ni), or titanium nitride (TiN). The gate contact via 520 may include cobalt (Co), nickel (Ni), tungsten (W), or ruthenium (Ru). The first contact via 540, the second contact via 542 and the third contact via 544 include tungsten (W). The fourth contact via 560, the fifth contact via 562, and the sixth contact via 564 include copper (Cu).

In some embodiments, the ESL 516 and the ESL 530 may be implemented with the first ESL stack 2002, the second ESL stack 2004 or the third ESL stack 2006 because the underlying contact feature is not made of refractory metal. Additionally, the first ESL stack 2002, the second ESL stack 2004 or the third ESL stack 2006 provide better etch control because the etch process produces compounds or polymer to prevent over etching. In some embodiments, the ESL 550 may be implemented with the fifth ESL stack 2010 or the gradient ESL 2180 because the metal oxide in the fifth ESL stack 2010 or the gradient ESL 2180 adhere well to the first contact via 540, the second contact via 542 and the third contact via 544, which are formed of tungsten (W), and are less subject to electromigration when put in contact with metal oxide. As described above, the fourth ESL stack 2008 may be more suitable to be used in metallization layers that are over the FinFET 500 and include metal line pitches greater than 90 nm.

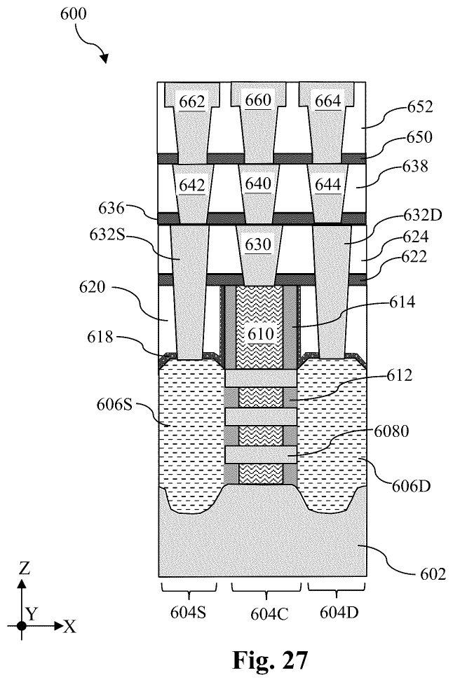

FIG. 27 illustrates implementation of ESLs to a gate-all-around (GAA) transistor 600. The GAA transistor 600 includes a vertical stack of channel members 6080 disposed over a substrate 602. The channel members 6080 may also be referred to as nanostructures. Depending on their cross-sectional shape, they may be referred to as nanosheets or nanowires. The channel members 6080 extend between a source feature 606S and a drain feature 606D along the X direction. A gate structure 610 wraps around each of the vertical stack of the channel members 6080. The gate structure 610 is laterally spaced apart from the source feature 606S or the drain feature 606D by a plurality of inner spacer features 612. Over the channel members 6080, the gate structure 610 is sandwiched between two top gate spacers 614. A contact etch stop layer (CESL) 618 is disposed over the source feature 606S and the drain feature 606D. An interlayer dielectric (ILD) layer 620 is disposed over the CESL 618. An ESL 622 is disposed over the gate structure 610, the top gate spacers 614, and the ILD layer 620. An IMD layer 624 is disposed over the ESL 622. A source contact 632S extends through the IMD layer 624, the ESL 622, the ILD layer 620, and the CESL 618 to couple to the source feature 606S. A gate contact via 630 extends through the IMD layer 624 and the ESL 622 to couple to the gate structure 610. A drain contact 632D extends through the IMD layer 624, the ESL 622, the ILD layer 620, and the CESL 618 to couple to the drain feature 606D. An ESL 636 is disposed over the IMD layer 624, the source contact 632S, the gate contact via 630 and the drain contact 632D. An IMD layer 638 is disposed over the ESL 636. A seventh contact via 640, an eighth contact via 642 and the nineth contact via 644 extend through the IMD layer 638 and the ESL 636 to couple to the gate contact via 630, the source contact 632S and the drain contact 632D, respectively. An ESL 650 is disposed over the IMD layer 638, the seventh contact via 640, the eighth contact via 642 and the nineth contact via 644. An IMD layer 652 is disposed over the ESL 650. A tenth contact via 660, an eleventh contact via 662 and the twelfth contact via 664 extend through the IMD layer 652 and the ESL 650 to couple to the seventh contact via 640, the eighth contact via 642 and the nineth contact via 644, respectively.

In some embodiments, the substrate 602 and the channel members 6080 may include silicon (Si). The source feature 606S and the drain feature 606D may be n-type or p-type. When they are n-type, they include silicon (Si) and an n-type dopant, such as phosphorus (P) or arsenic (As). When they are p-type, they include silicon germanium (SiGe) and a p-type dopant, such as boron (B). The gate structure 610 includes an interfacial layer to interface the channel members 6080, a gate dielectric layer over the interfacial layer, and a gate electrode over the gate dielectric layer. The interfacial layer may include silicon oxide. The gate dielectric layer may include a high-k dielectric material, such as hafnium oxide. The gate electrode may include titanium nitride, titanium aluminum, titanium aluminum nitride, titanium, tantalum, or tungsten. The top gate spacers 614 and the inner spacer features 612 may include silicon oxide, silicon nitride, silicon oxynitride, silicon oxycarbonitride, or silicon oxycarbide. The CESL 618 may include silicon nitride or silicon oxynitride. The ILD layer 620, the IMD layer 624, the IMD layer 638 and the IMD layer 652 may include a porous organosilicate thin film (e.g., SiOCH), tetraethylorthosilicate (TEOS) oxide, un-doped silicate glass, borophosphosilicate glass (BPSG), fluorosilicate glass (FSG), phosphosilicate glass (PSG), fluorine-doped silicon dioxide, carbon-doped silicon dioxide, porous silicon dioxide, porous carbon-doped silicon dioxide, silicon oxycarbonitride (SiOCN), spin-on silicon based polymeric dielectrics, or combinations thereof. The source contact 632S and the drain contact 632D may include cobalt (Co), nickel (Ni), or titanium nitride (TiN). The gate contact via 630 may include cobalt (Co), nickel (Ni), tungsten (W), or ruthenium (Ru). The seventh contact via 640, the eighth contact via 642 and the nineth contact via 644 include tungsten (W). The tenth contact via 660, the eleventh contact via 662 and the twelfth contact via 664 include copper (Cu).

In some embodiments, the ESL 622 and the ESL 636 may be implemented with the first ESL stack 2002, the second ESL stack 2004, or the third ESL stack 2006 because the underlying contact feature is not made of refractory metal. Additionally, the first ESL stack 2002, the second ESL stack 2004, or the third ESL stack 2006 provide better etch control because the etch process produces compounds or polymer to prevent over etching. In some embodiments, the ESL 650 may be implemented with the fifth ESL stack 2010 or the gradient ESL 2180 because the metal oxide in the fifth ESL stack 2010 or the gradient ESL 2180 adhere well to the seventh contact via 640, the eighth contact via 642 and the nineth contact via 644, which are formed of tungsten (W), and are less subject to electromigration when put in contact with metal oxide. As described above, the fourth ESL stack 2008 may be more suitable to be used in metallization layers that are over the GAA transistor 600 and include metal line pitches greater than 90 nm.

Thus, one of the embodiments of the present disclosure provides a method. The method includes receiving a workpiece that includes a conductive feature embedded in a first dielectric layer, treating the workpiece with a nitrogen-containing plasma, after the treating, depositing a first etch stop layer (ESL) over the workpiece, depositing a second ESL over the first ESL, depositing a second dielectric layer over the second ESL, forming an opening through the second dielectric layer, the second ESL and the first ESL to expose the conductive feature, and forming a contact via in the opening. The first ESL includes aluminum nitride or silicon carbonitride and the second ESL includes aluminum oxide or silicon oxycarbide.

In some embodiments, the conductive feature includes copper (Cu). In some embodiments, the nitrogen-containing plasma includes ammonia plasma and nitrogen plasma. In some implementations, the method further includes before the depositing of the second ESL, depositing a middle ESL over the first ESL. In some instances, a composition of the middle ESL is different from either a composition of the first ESL or the second ESL. In some embodiments, the middle ESL includes oxygen-doped silicon carbide. In some embodiments, the depositing of the middle ESL includes use of tetramethylsilane, silane, trimethylsilane, carbon dioxide, xenon, oxygen, or a combination thereof. In some embodiments, the first ESL includes a bottom surface closer to the conductive feature and a top surface away from the conductive feature and a nitrogen content at the bottom surface is greater than a nitrogen content at the top surface.

In another of the embodiments, a contact structure is provided. The contact structure includes a conductive feature embedded in a first dielectric layer, a first etch stop layer (ESL) over the conductive feature and the first dielectric layer, a second ESL over the first ESL, a second dielectric layer over the second ESL, and a contact via extending through the second dielectric layer, the second ESL, and the first ESL to couple to the conductive feature. The first ESL includes aluminum nitride or silicon carbonitride and the second ESL includes aluminum oxide or silicon oxycarbide.

In some embodiments, the conductive feature includes copper. In some embodiments, the contact structure further includes a middle ESL sandwiched between the first ESL and the second ESL. In some implementations, the middle ESL includes silicon oxycarbide. In some embodiments, top surfaces of the conductive feature and the first dielectric layer are coplanar. In some instances, the first ESL includes a bottom surface closer to the conductive feature and a top surface away from the conductive feature and a nitrogen content at the bottom surface is greater than a nitrogen content at the top surface.

In yet another of the embodiments, a method is provided. The method includes receiving a workpiece that includes a conductive feature embedded in a first dielectric layer, depositing a first etch stop layer (ESL) over the workpiece such that the first ESL is in direct contact with top surfaces of the conductive feature and the first dielectric layer, depositing a second ESL over the first ESL, depositing a second dielectric layer over the second ESL, forming an opening through the second dielectric layer, the second ESL and the first ESL to expose the conductive feature, and forming a contact via in the opening. The first ESL includes metal oxide.

In some embodiments, the conductive feature includes tungsten (W). In some embodiments, the first ESL includes aluminum oxide. In some implementations, the second ESL includes metal nitride or metal oxide. In some instances, when the second ESL includes metal oxide, an oxygen content in the second ESL and greater than an oxygen content in the first ESL. In some embodiments, the second ESL includes aluminum nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising a conductive feature embedded in a first dielectric layer;
treating the workpiece with a nitrogen-containing plasma;
after the treating, depositing a first etch stop layer (ESL) over the workpiece;
depositing a second ESL over the first ESL;
depositing a second dielectric layer over the second ESL;
forming an opening through the second dielectric layer, the second ESL and the first ESL to expose the conductive feature; and
forming a contact via in the opening,
wherein the first ESL comprises aluminum nitride or silicon carbonitride,
wherein the second ESL comprises aluminum oxide or silicon oxycarbide.

2. The method of claim 1, wherein the conductive feature comprises copper (Cu).

3. The method of claim 1, wherein the nitrogen-containing plasma comprises ammonia plasma and nitrogen plasma.

4. The method of claim 1, further comprising:
before the depositing of the second ESL, depositing a middle ESL over the first ESL.

5. The method of claim 4, wherein a composition of the middle ESL is different from either a composition of the first ESL or the second ESL.

6. The method of claim 4, wherein the middle ESL comprises oxygen-doped silicon carbide.

7. The method of claim 4, wherein the depositing of the middle ESL comprises use of tetramethylsilane, silane, trimethylsilane, carbon dioxide, xenon, oxygen, or a combination thereof.

8. The method of claim 1,
wherein the first ESL comprises a bottom surface closer to the conductive feature and a top surface away from the conductive feature,
wherein a nitrogen content at the bottom surface is greater than a nitrogen content at the top surface.

9. A contact structure, comprising:
a conductive feature embedded in a first dielectric layer;
a first etch stop layer (ESL) over the conductive feature and the first dielectric layer;
a second ESL over the first ESL;
a second dielectric layer over the second ESL; and
a contact via extending through the second dielectric layer, the second ESL, and the first ESL to couple to the conductive feature,
wherein the first ESL comprises aluminum nitride or silicon carbonitride,
wherein the second ESL comprises aluminum oxide or silicon oxycarbide.

10. The contact structure of claim 9, wherein the conductive feature comprises copper.

11. The contact structure of claim 9, further comprising:
a middle ESL sandwiched between the first ESL and the second ESL.

12. The contact structure of claim 11, wherein the middle ESL comprises silicon oxycarbide.

13. The contact structure of claim 9, wherein top surfaces of the conductive feature and the first dielectric layer are coplanar.

14. The contact structure of claim 9,
wherein the first ESL comprises a bottom surface closer to the conductive feature and a top surface away from the conductive feature,
wherein a nitrogen content at the bottom surface is greater than a nitrogen content at the top surface.

15. A method, comprising:
receiving a workpiece comprising a conductive feature embedded in a first dielectric layer;
depositing a first etch stop layer (ESL) over the workpiece such that the first ESL is in direct contact with top surfaces of the conductive feature and the first dielectric layer;
depositing a second ESL over the first ESL;
depositing a second dielectric layer over the second ESL;
forming an opening through the second dielectric layer, the second ESL and the first ESL to expose the conductive feature; and
forming a contact via in the opening,
wherein the first ESL comprises metal oxide.

16. The method of claim 15, wherein the conductive feature comprises tungsten (W).

17. The method of claim 15, wherein the first ESL comprises aluminum oxide.

18. The method of claim 15, wherein the second ESL comprises metal nitride or metal oxide.

19. The method of claim 18, wherein when the second ESL comprises metal oxide, an oxygen content in the second ESL and greater than an oxygen content in the first ESL.

20. The method of claim 15, wherein the second ESL comprises aluminum nitride.
